(19) United States
(12) Patent Application Publication
(10) Pub. No.: US 2026/0117383 A1
(43) Pub. Date: Apr. 30, 2026

(54) SEALING SYSTEM FOR HIGH TEMPERATURE REACTION CHAMBERS

(71) Applicant: ASM IP Holding B.V., Almere (NL)

(72) Inventor: Kenneth Honniball, Kessel-Lo (Leuven) (BE)

(21) Appl. No.: 19/334,890

(22) Filed: Sep. 21, 2025

Related U.S. Application Data
(60) Provisional application No. 63/697,627, filed on Sep. 23, 2024.

(51) Int. Cl. C23C 16/458; C23C 16/44; C23C 16/52

(52) U.S. Cl. CPC C23C 16/4585; C23C 16/4409; C23C 16/52

(57) ABSTRACT

A reaction chamber may comprise a susceptor configured to support a substrate disposed in the reaction chamber volume, an upper chamber space above the susceptor, a lower chamber space below the susceptor, and/or a sealing system. The sealing system may cause the upper chamber space and the lower chamber space to be at least partially fluidly separate. The sealing system may comprise a spacer plate surrounding the susceptor and/or a flexible diaphragm coupled to the susceptor. The sealing system may be configured to form at least a partial seal between the spacer plate and the extension plate and cause at least partial fluid separation between the upper chamber space and the lower chamber space by causing bending of the flexible diaphragm such that a bent portion of the flexible diaphragm is at least in partial contact with the spacer plate.

### CROSS-REFERENCE TO RELATED APPLICATION(S)

This Application claims the benefit of U.S. Provisional Application 63/697,627 filed on Sep. 23, 2024, the entire contents of which are incorporated herein by reference.

### FIELD OF INVENTION

The present disclosure relates generally to a semiconductor processing or reactor system. Particularly, the present disclosure relates to a reactor system and to components comprised therein, which allow sealing between an upper and lower volume within a reaction chamber.

### BACKGROUND OF THE DISCLOSURE

Reaction chambers may be used for a variety of processes during the formation of electronic devices on semiconductor substrates. For example, reaction chambers can be used for depositing various material layers onto the semiconductor substrates, etching materials, and/or cleaning surfaces.

Reaction chambers may comprise two spaces or volumes that are separated, for example, by a susceptor. The two spaces may comprise an upper chamber space above the susceptor and/or a lower chamber space below the susceptor. The lower chamber space may be disposed vertically below the upper chamber space, while the upper chamber space may be disposed vertically above the susceptor. Processing operations of one or more substrates may occur in the upper reaction space, and during the operations, contaminants may undesirably transfer from one chamber space to another. For example, contaminants may undesirably transfer from the upper chamber space to the lower chamber space. Furthermore, if the lower chamber space is sealed off from the upper chamber space, the overall volume of space where processing operations of substrates occur may be reduced, and therefore, less quantity of materials may be used during the formation of electronic devices on the substrates. Therefore, systems and methods for providing a seal between the two spaces within the reaction chamber (e.g., to at least partially fluidly separate the two chambers) may be desirable.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

The reactor system disclosed herein may facilitate at least partial sealing between two spaces, chambers, or volumes within a reaction chamber of a reactor system. In various embodiments, the reactor system may comprise a reaction chamber where one of the two spaces within the reaction chamber may be in fluid communication with the other space. The reaction chamber may comprise: a susceptor configured to support a substrate disposed in the reaction chamber and translate upwardly and downwardly within the reaction chamber; an upper chamber space within the reaction chamber and above the susceptor; a lower chamber space within the reaction chamber and below the susceptor; and a sealing system comprising a spacer plate surrounding the susceptor and a flexible diaphragm coupled to the susceptor. The sealing system may be configured to cause at least partial fluid separation between the upper chamber space and the lower chamber space by causing a portion of the flexible diaphragm to bend, and the bent portion of the flexible diaphragm may be at least in partial contact with the spacer plate.

In various embodiments, the sealing system may further comprise an electromagnetic source coupled to the spacer plate. The sealing system may be configured to cause bending of the flexible diaphragm by causing the susceptor to move up within the reaction chamber, causing an upward-facing surface of the flexible diaphragm to be in proximity to a downward-facing surface of the spacer plate, and activating the electromagnetic source to expose the flexible diaphragm to an electromagnetic or magnetic field.

In various embodiments, the sealing system may further comprise a stopper ring attached to the downward-facing surface of the spacer plate. The stopper ring may be configured to prevent particulates from being deposited on the flexible diaphragm when the bent portion of the flexible diaphragm is in contact with the spacer plate.

In various embodiments, the sealing system may further comprise an extension plate attached to the susceptor, and the flexible diaphragm may be attached to an upward-facing surface of the extension plate. In various embodiments, the sealing system may be configured to cause the susceptor to move up within the reaction chamber till the upward-facing surface of the extension plate is in contact with the stopper ring.

In various embodiments, the downward-facing surface of the spacer plate may comprise a concave portion, and the bent portion of the flexible diaphragm may be in contact with the concave portion of the spacer plate.

In various embodiments, the sealing system may be further configured to cause fluid communication between the upper chamber space and the lower chamber space by deactivating the electromagnetic source and causing the susceptor to move down within the reaction chamber.

In various embodiments, the extension plate may comprise a non-magnetic metal or a non-magnetic metal alloy. In various embodiments, the flexible diaphragm may comprise a magnetic metal or a magnetic metal alloy. In various embodiments, the spacer plate may comprise a ceramic material. In various embodiments, the reaction chamber may be configured to process the substrate at a temperature of less than 600° C.

In various embodiments, a method may comprise: translating a susceptor, in a reaction chamber, upwardly from a first position to a second position where the reaction chamber may comprise an upper chamber space above the susceptor and a lower chamber space below the susceptor; causing at least partial fluid separation between the upper chamber space and the lower chamber space by activating an electromagnetic source to expose a flexible diaphragm, coupled to the susceptor, to an electromagnetic or magnetic field; and causing, based on the electromagnetic field, bending of the flexible diaphragm such that a bent portion of the flexible diaphragm is at least in partial contact with a spacer plate surrounding the susceptor; and maintaining, during the processing of a substrate within the upper chamber space, the partial fluid separation between the upper chamber space and the lower chamber space.

In various embodiments, the flexible diaphragm may be attached to the upward-facing surface of the extension plate. Translating the susceptor to the second position may comprise causing an upward-facing surface of an extension plate attached to the susceptor to be in contact with a stopper ring coupled to a downward-facing surface of the spacer plate.

In various embodiments, a downward-facing surface of the spacer plate may comprise a concave portion, and the bent portion of the flexible diaphragm may be in contact with the concave portion of the spacer plate.

In various embodiments, the method may further comprise, after the processing of the substrate, deactivating the electromagnetic source and translating the susceptor downward from the second position to a third position.

For the purpose of summarizing the disclosure and the advantages achieved over the prior art, certain objects and advantages of the disclosure have been described herein above. Of course, it is to be understood that not necessarily all such objects or advantages may be achieved in accordance with any particular embodiment of the disclosure. Thus, for example, those skilled in the art will recognize that the embodiments disclosed herein may be carried out in a manner that achieves or optimizes one advantage or group of advantages as taught or suggested herein without necessarily achieving other objects or advantages as may be taught or suggested herein.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWING FIGURES

While the specification concludes with claims particularly pointing out and distinctly claiming what are regarded as embodiments of the disclosure, the advantages of embodiments of the disclosure may be more readily ascertained from the description of certain examples of the embodiments of the disclosure when read in conjunction with the accompanying drawings. Elements with the like element numbering throughout the figures are intended to be the same.

FIG. 1 is a schematic diagram of an exemplary reactor system in accordance with various embodiments.

FIG. 2A is a schematic diagram of an exemplary reaction chamber with a susceptor disposed in a lower position, in accordance with various embodiments.

FIG. 2B is a schematic diagram of an exemplary reaction chamber with a susceptor disposed in a raised position, in accordance with various embodiments.

FIGS. 3A, 3B, and 3C illustrate an exemplary susceptor in accordance with various embodiments.

FIGS. 4A and 4B illustrate an exemplary spacer plate for providing a seal within a reaction chamber in accordance with various embodiments.

FIG. 5 illustrates a method for maintaining a seal within a reaction chamber in accordance with various embodiments.

FIGS. 6, 7, 8, and 9 illustrate schematic diagrams of a portion of a reaction chamber in accordance with various embodiments.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, apparatus, structure, or device, but are merely representations that are used to describe embodiments of the disclosure.

As used herein, the term “substrate” may refer to any underlying material or materials, including any underlying material or materials that may be modified, or upon which, a device, a circuit, or a film may be formed.

As used herein, the term “atomic layer deposition” (ALD) may refer to a vapor deposition process in which deposition cycles, preferably a plurality of consecutive deposition cycles, are conducted in a process chamber. Typically, during each cycle, the precursor is chemisorbed to a deposition surface (e.g., a substrate surface or a previously deposited underlying surface such as material from a previous ALD cycle), forming a monolayer or sub-monolayer that does not readily react with additional precursor (e.g., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as “chemical vapor atomic layer deposition,” “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) may refer to any process wherein a substrate is exposed to one or more volatile precursors, which react and/or decompose on a substrate surface to produce a desired deposition.

As used herein, the terms “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise a material or a layer with pinholes, but still be at least partially continuous.

As used herein, the term “contaminant” may refer to any unwanted material disposed within the reaction chamber that may affect the purity of a substrate disposed in the reaction chamber. The term “contaminant” may refer to, but is not limited to, unwanted deposits, metal and nonmetal particles, impurities, and waste products, disposed within the reactor system or reaction chamber, or any portion thereof.

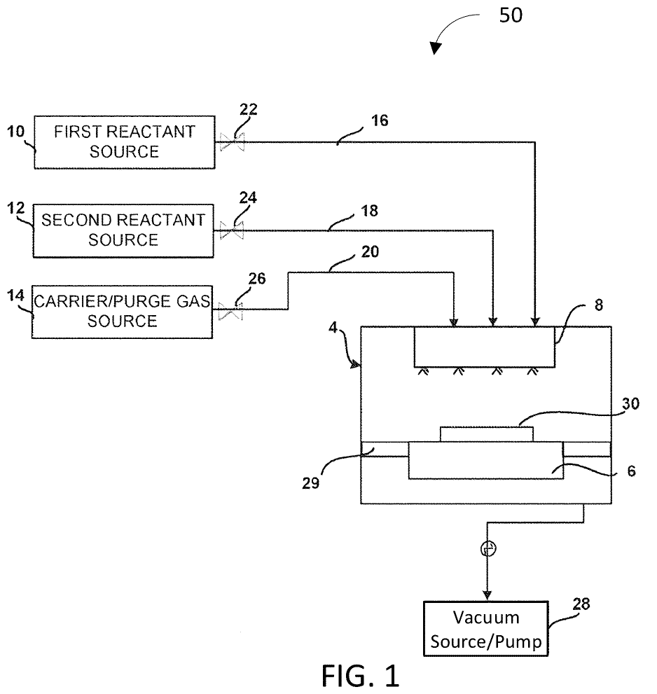

Reactor systems used for ALD, CVD, and/or the like, may be used for a variety of applications, including depositing and etching materials on a substrate surface. In various embodiments, with reference to FIG. 1, a reactor system 50 may comprise a reaction chamber 4, a susceptor 6 to hold a substrate 30 during processing, a fluid distribution system 8 (e.g., a showerhead) to distribute one or more reactants to a surface of substrate 30, one or more reactant sources 10, 12, and/or a carrier and/or purge gas source 14, fluidly coupled to reaction chamber 4 via lines 16, 18, and 20, and/or valves or controllers 22, 24, and 26. The reactor system 50 may also comprise a vacuum source/pump 28 fluidly coupled to the reaction chamber 4. One or more sealing systems 29 may separate (e.g., at least partially separate fluidly) portions of a volume within reaction chamber 4.

While FIG. 1 illustrates the sealing systems 29 being implemented in a vertical furnace (e.g., the reactor system 50) accommodating a single substrate (e.g., substrate 30) oriented substantially horizontally. The sealing systems described herein may also be implemented in vertical batch furnaces that accommodate multiple substrates, diffusion ovens, horizontal furnaces where wafers are oriented vertically, and/or other furnaces used for the processing of semiconductor substrates.

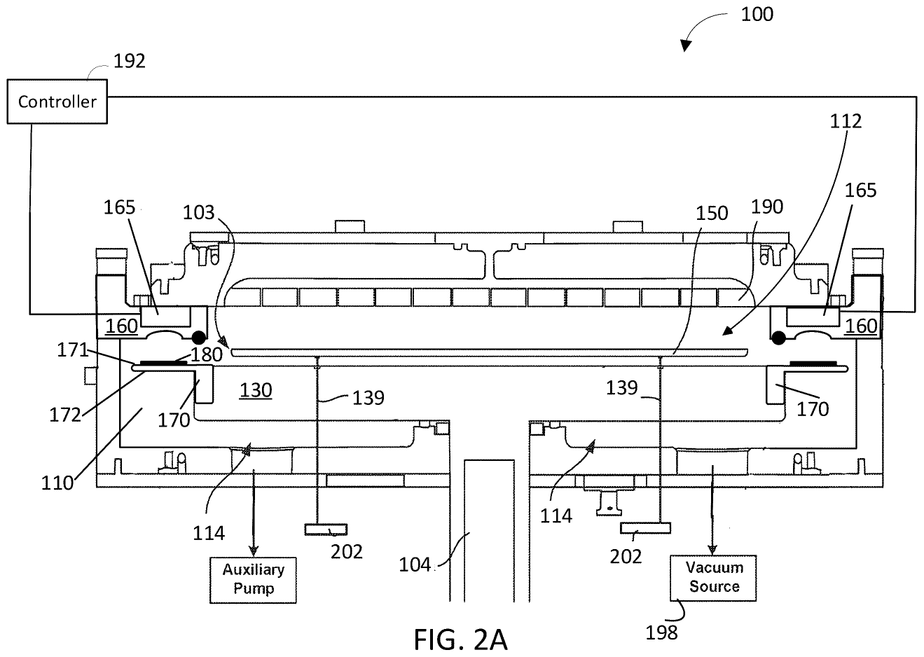

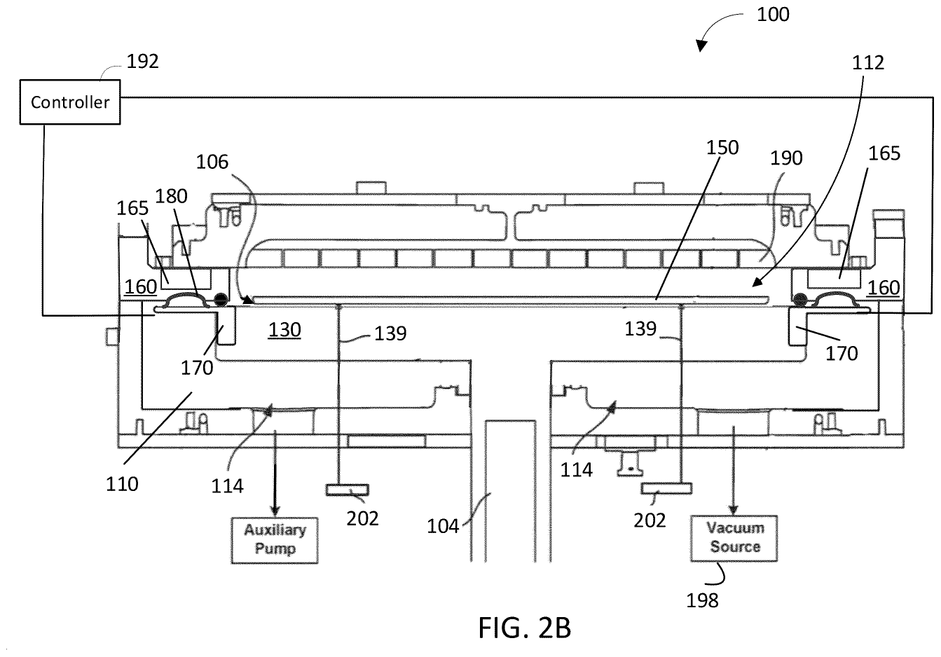

Turning to FIGS. 2A and 2B, the embodiments of the disclosure may include reactor systems and methods that may be utilized for processing a substrate within a reactor 100. In various embodiments, a reactor 100 may comprise a reaction chamber 110 for processing substrates. In various embodiments, the reaction chamber 110 may comprise an upper chamber space 112, which may be configured for processing one or more substrates, and/or a lower chamber space 114. The lower chamber space 114 may be configured for the loading and unloading of substrates from the reaction chamber, and/or for providing a pressure differential between lower chamber space 114 and the upper chamber space 112.

The lower chamber space 114 may be coupled to a vacuum source 198 (e.g., a vacuum pump). The vacuum source 198, when activated, may provide vacuum pressure, causing gas to flow from the vacuum source 198 to the lower chamber space 114. The vacuum source 198, when deactivated, may cause gas to flow from the lower chamber space 114 to the vacuum source 198.

In various embodiments, the reactor 100 may be configured to process the substrate below 800° C. In various embodiments, the reactor 100 may be configured to process the substrate below 600° C. In various embodiments, the reactor 100 may be configured to process the substrate below 550° C.

In various embodiments, a substrate 150 and a susceptor 130 may be movable relative to one another. For example, in various embodiments, lift pins 139 may be configured to allow substrate 150 to separate from susceptor 130 and/or to allow substrate 150 to be placed in contact with (i.e., to be supported by) susceptor 130. In various embodiments, the susceptor 130 may move, for example, via a susceptor elevator 104, up or down such that the substrate 150 moves with the susceptor 130. In various embodiments, the lift pins 139 may move up or down, for example, via lift pin elevators/platforms 202. In various embodiments, one of the susceptor 130 and the lift pins 139 may be stationary while the other is moving.

In various embodiments, the susceptor 130 may move from the loading position 103 to the processing position 106 as illustrated in FIG. 2B, thus moving the substrate 150 into the upper chamber space 112. The substrate 150 may be subsequently processed within the upper chamber space 112. Fluids (e.g., precursors, reactant gases, carrier gases, and the like) may flow into the upper chamber space 112 through a fluid distribution system 190 (e.g., a showerhead) to contact the substrate 150. A volume of the upper chamber space 112 within the reaction chamber 110 may be enclosed at least by the fluid distribution system 190, the susceptor 130, a spacer plate 160, an extension plate 170, and/or a flexible diaphragm 180.

The extension plate 170 may be set around the susceptor 130. The extension plate 170 may be ring-shaped and/or attached to the susceptor 130. The extension plate 170 may have an inner periphery that has a diameter greater than a diameter of the substrate-supporting area on the susceptor 130. The susceptor 130 may have an annular lip portion on its top surface outside the substrate-supporting area, and the extension plate 170 may be disposed on the top surface outside the lip portion. Alternatively, the susceptor 130 may have no annular lip portion on a top surface outside the substrate-supporting area, and the extension plate 170 may be disposed on the top surface outside the substrate-supporting area.

The susceptor 130 may comprise a top plate (not shown) and a heating block (not shown) on which the top plate is placed. The extension plate 170 may be ring-shaped and interposed between the top plate and the heating block. The extension plate 170 may be attached to a side of the heating block. The extension plate 170 may have a ring portion and an annular peripheral portion that extends from the susceptor 130. The ring portion may be attached to a side of the heating block. The annular peripheral portion may comprise an upward-facing surface 171 and a downward facing surface 172. A flexible diaphragm 180 may be partially attached to the upward-facing surface 171 of the extension plate 170. The flexible diaphragm 180 may be ring-shaped.

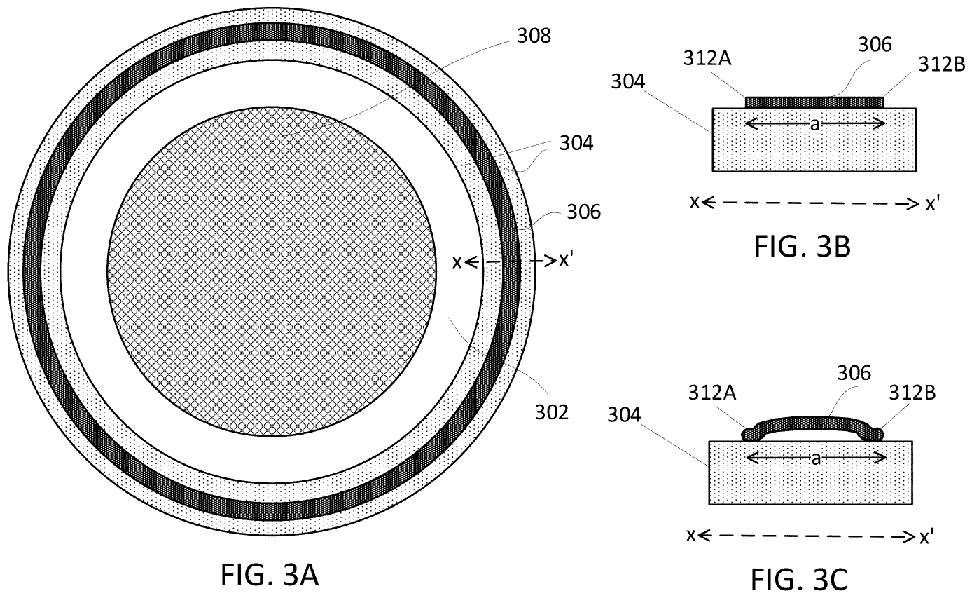

FIG. 3A illustrates a top view of an upward-facing surface of an example susceptor 302 (e.g., the susceptor 130), while FIGS. 3B and 3C illustrate example cross-sectional views of the extension plate 304. The susceptor 302 may support a substrate 308 (e.g., the substrate 150). A ring-shaped extension plate 304 (e.g., the extension plate 170) may surround, be in contact with, and/or be attached to the perimeter of the susceptor 302.

A flexible diaphragm 306 (e.g., the flexible diaphragm 180) may be disposed on the upward-facing surface of the extension plate 304. The flexible diaphragm 306 may be ring-shaped and/or may comprise an inner peripheral edge 312A and an outer peripheral edge 312B. In various embodiments, the extension plate 304 may have a first circumference C1, the outer peripheral edge 312B of the flexible diaphragm 306 may have a second circumference C2, the inner peripheral edge 312A of the flexible diaphragm 306 may have a third circumference C3, and the susceptor 302 may have a fourth circumference C4. The second circumference C2 may be less than the first circumference C1 and greater than the third circumference C3. The third circumference C3 may be less than the second circumference C2 and greater than the fourth circumference C4. The first circumference C1 may be greater than the second, third, and fourth circumferences C2, C3, C4. The width “a” of the flexible diaphragm 306 may be in the range of 10 to 30 nanometers.

The inner peripheral edge 312A and the outer peripheral edge 312B of the flexible diaphragm 306 may be attached to the extension plate 304. While a portion of the flexible diaphragm 306, between the inner peripheral edge 312A and the outer peripheral edge 312B, may separate from the extension plate 304 when the flexible diaphragm 306 is exposed to an electromagnetic field, the inner peripheral edge 312A and the outer peripheral edge 312B may stay attached to the extension plate 304.

The extension plate 304 may comprise a material such as quartz, ceramic, or a metal, such as titanium, aluminum, or Hastelloy. The flexible diaphragm 306 may comprise a soft magnetic metal or a soft magnetic metal alloy. Soft magnetic metals or metal alloys may be materials that can be easily magnetized when exposed to an electromagnetic or magnetic field. Additionally, soft magnetic metals or metal alloys may be easily demagnetized when the electromagnetic or magnetic field is removed. Examples of soft magnetic metals or metal alloys may include steel, nickel-iron alloy, silicon-iron alloy, iron, iron-cobalt alloy, ferritic stainless steels, iron-nickel, soft ferrites, and the like. Alternatively, the flexible diaphragm 306 may comprise a hard magnetic metal or a hard magnetic metal alloy. Hard magnetic metals or metal alloys may be materials that can retain magnetization even in the absence of an electromagnetic or magnetic field.

In various embodiments, when the flexible diaphragm 306 is not exposed to an electromagnetic or magnetic field, and as illustrated in FIG. 3B, the middle portion of the flexible diaphragm 306, between the inner peripheral edge 312A and the outer peripheral edge 312B, may be in contact with the upward-facing surface of the extension plate 304. Alternatively, in the absence of an electromagnetic or magnetic field and as illustrated in FIG. 3C, the middle portion of the flexible diaphragm 306 may be raised relative to the inner peripheral edge 312A and the outer peripheral edge 312B.

Referring back to FIGS. 2A and 2B, the extension plate 170 may move with the susceptor when the susceptor 130 is raised or lowered inside the reaction chamber. When the susceptor 130 is raised to the processing position 106, a portion of the upward-facing surface of the extension plate 170 and/or a portion of the flexible diaphragm 180 may be in contact with a spacer plate 160 of the reactor 100.

In various embodiments, at least a portion of the spacer plate 160 may be protruding from the chamber side wall into the reaction chamber. The spacer plate 160 may be disposed below the fluid distribution system 190. In various embodiments, the spacer plate 160 may surround the susceptor in the reaction chamber 110. The spacer plate 160 may be coupled with the extension plate 170 when the susceptor 130 moves into or is disposed in a processing position (e.g., a raised position). For example, a downward-facing surface of the spacer plate 160 may be coupled with and/or in contact with an upward-facing surface of the flexible diaphragm 180 or the extension plate 170. The spacer plate 160 may be coupled to an electromagnetic source 165 (e.g., an electromagnetic coil). The electromagnetic source 165, when activated, may generate an electromagnetic or magnetic field, and the flexible diaphragm 180 may be exposed to the electromagnetic or magnetic field generated by the electromagnetic source 165.

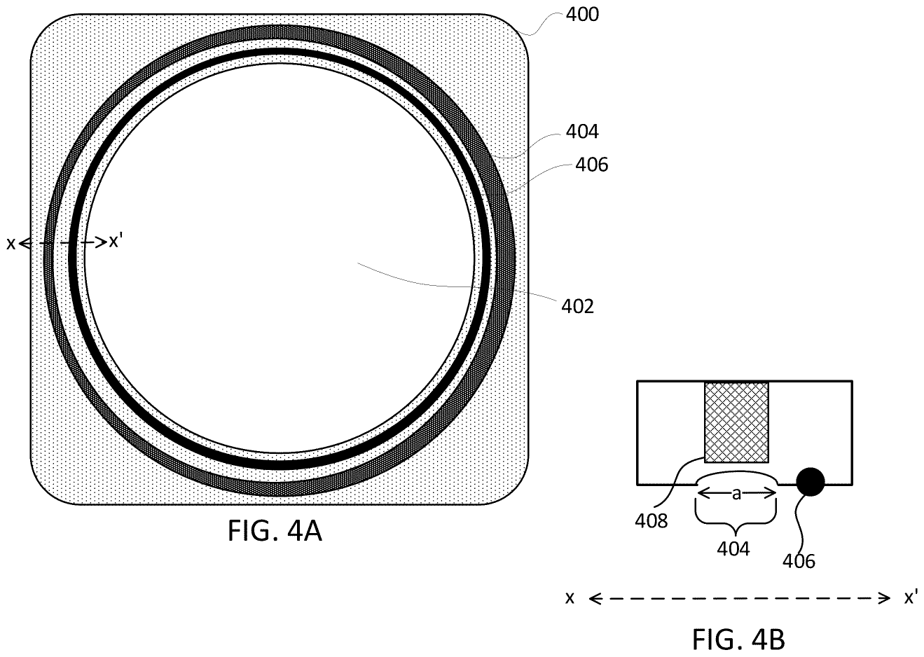

FIG. 4A illustrates a top view of a downward-facing surface of an example spacer plate 400 (e.g., the spacer plate 160), while FIG. 4B illustrates a cross-sectional view of the spacer plate 400. The spacer plate 400 may comprise an opening 402 that enables fluids from the fluid distribution system 190 to enter the upper chamber space 112. The spacer plate 400 may further comprise a stopper ring 406 and/or a concave portion 404. The stopper ring 406 may be configured to prevent particulates from being deposited on the flexible diaphragm 180 when a substrate is being processed in the upper chamber space 112. An electromagnetic source 408 (e.g., the electromagnetic source 165) may be disposed above the concave portion 404.

The width “a” of the concave portion 404 may be in the range of 10 to 30 nanometers. While FIG. 4B illustrates a concave portion 404 having a semi-elliptical shape, the concave portion 404 may also be of a semi-circular shape, bell shape, rectangular shape, triangular shape, trapezoidal shape, and the like. Similarly, while FIG. 4B illustrates the stopper ring 406 having a circular shaped cross-section, the stopper ring 406 may also be of a square cross-section, a triangular cross-section, an elliptical cross-section, a rectangular cross-section, a trapezoidal cross-section, and the like. In various embodiments, the circumference of the concave portion 404 may be greater than the circumference of the stopper ring 406 and/or the circumference of the opening 402. In various embodiments, the circumference of the stopper ring 406 may be greater than the circumference of the opening 402 and/or may be less than the circumference of the concave portion 404. The spacer plate 400 and/or the stopper ring 406 may comprise a material such as quartz, ceramic, or a metal, such as titanium, aluminum, stainless steel, or Hastelloy.

Referring back to FIGS. 2A and 2B, in various embodiments, to create a separation between the upper chamber space 112 and the lower chamber space 114, the reaction chamber 110 may comprise a sealing system disposed between the susceptor 130, the chamber sidewalls of the reaction chamber, and/or the fluid distribution system 190. For example, the sealing system in reaction chamber 110 may comprise the extension plate 170 attached to the susceptor 130, the flexible diaphragm 180 attached to the extension plate 170, the spacer plate 160, the stopper ring 406, the electromagnetic source 165, and/or the controller 192 to separate or isolate the upper chamber space 112 and the lower chamber space 114.

The sealing system in the reaction chamber 110 may be configured to control fluid flow within a reaction chamber. The upper chamber space 112 and the lower chamber space 114 may be fluidly separated by creating at least a partial seal between a portion of the flexible diaphragm 180 and a portion of the spacer plate 160. The partial seal may be created when the susceptor 130 is at the raised position 103, such that the upward-facing surface 171 of the extension plate 170 is in contact with the stopper ring 406 of the spacer plate 160. When the susceptor 130 is at the raised position, the electromagnetic source 165 may be activated to generate an electromagnetic or magnetic field. The electromagnetic or magnetic field may enable a portion (e.g., the middle portion between the inner peripheral edge 312A and the outer peripheral edge 312B) to bend, deform, and/or expand such that bent, deformed, and/or expanded portion of the flexible diaphragm 180 is in contact with the concave portion of the spacer plate 160 disposed below the electromagnetic source 165. The bending, deformation, and/or expansion of the flexible diaphragm 180 may be caused by the soft or hard magnetic material in the flexible diaphragm 180 being attracted to the electromagnetic or magnetic field generated by the electromagnetic source 165. The electromagnetic source 165, when deactivated, may cause the bent, deformed, and/or expanded portion of the flexible diaphragm 180 to relax back to the original shape of the flexible diaphragm 180, thereby releasing the seal. If the flexible diaphragm 180 comprises a soft magnetic metal or metal alloy, the magnetic field generated by the electromagnetic source 165 may magnetize the flexible diaphragm 180. Once the magnetic field is turned off when the electromagnetic source is deactivated, the flexible diaphragm 180 comprising a soft magnetic metal or metal alloy may demagnetize. A controller 192 may control the separation and/or fluid communication between the upper chamber space 112 and the lower chamber space 114 by controlling the activating and/or deactivating of the electromagnetic source 165.

Separation and/or isolation between the upper chamber space 112 and the lower chamber space 114 may be desirable to prevent or reduce precursor gases, and/or other fluids, utilized in the processing of a substrate 150, from entering and/or contacting the lower chamber space 114 of reaction chamber 110. For example, the precursor gases utilized for processing substrates in the reaction space may comprise corrosive deposition precursors, which may contact the lower chamber space 114, producing unwanted deposits/contaminants/particles, which may, in turn, be reintroduced into the upper chamber space 112 later on, thereby providing a source of contamination to a substrate disposed in the reaction space. The isolation of the upper chamber space 112 from the lower chamber space 114 may also limit the area in which plasma is generated. Various other embodiments described herein may also prevent plasma from coming in contact with the side faces of the susceptor (e.g., a heating block), interior walls of the reactor 100 and other locations where conductive members are exposed, which consequently results in a lower floating potential applied to the processing target. As a result, occurrences of charging damage caused by plasma and pickup problems may be reduced.

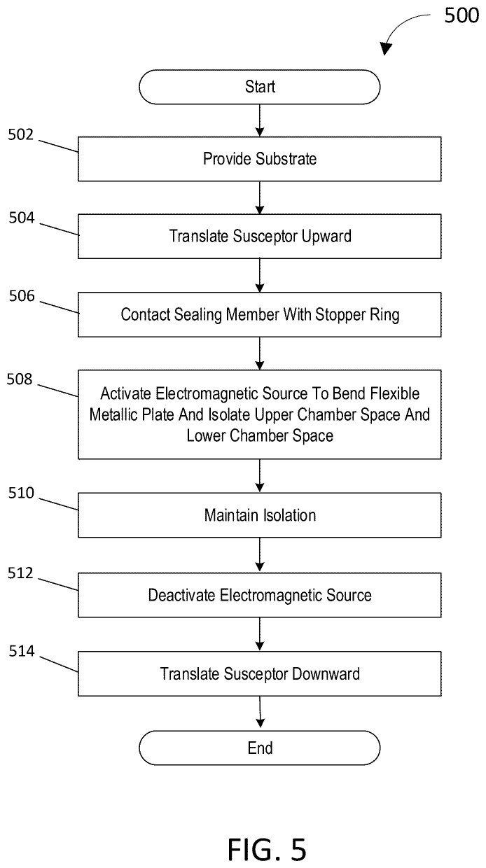

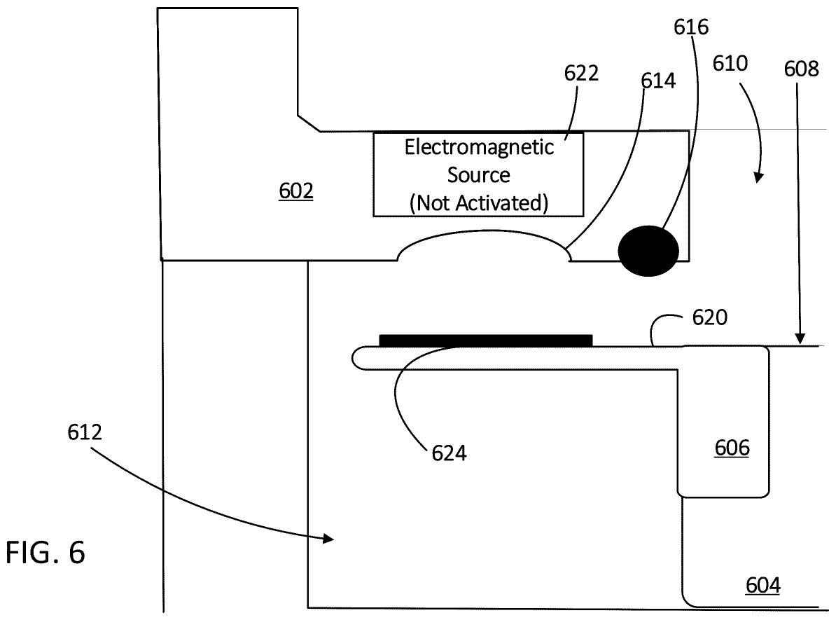

In operation, with reference to method 500 shown in FIG. 5, at step 502, a substrate (e.g., substrate 150) may be provided in a reaction chamber (e.g., the reaction chamber 110 of the reactor 100). At the time when the substrate is provided, the susceptor supporting the substrate may be at a first position (e.g., a lower position or loading position). For example, FIG. 6 illustrates a susceptor 604 (e.g., the susceptor 130) where the upward-facing surface of the susceptor 604 may be at the first position 608 (e.g., a lower position or loading position). An extension plate 606 (e.g., the extension plate 170) may be attached to the susceptor 604, and when the susceptor 604 is at first position 608, the upward-facing surface 620 of the extension plate 606 is not in contact with the stopper ring 616 (e.g., the stopper ring 406) of the spacer plate 602 (e.g., the spacer plate 160, 400). Additionally, the flexible diaphragm 624 (e.g., the flexible diaphragm 180) may not be in proximity of the concave portion 614 (e.g., the concave portion 404) of the spacer plate 602. The spacer plate 602 may also comprise an electromagnetic source 622 (e.g., the electromagnetic source 165). When the upward-facing surface of the susceptor 604 is at the first position 608, fluid may flow freely between the upper chamber space 610 (e.g., the upper chamber space 112) and the lower chamber space 612 (e.g., the lower chamber space 114). Accordingly, the flexible diaphragm 624 may be in a relaxed condition (e.g., no deformation, bending, or expansion).

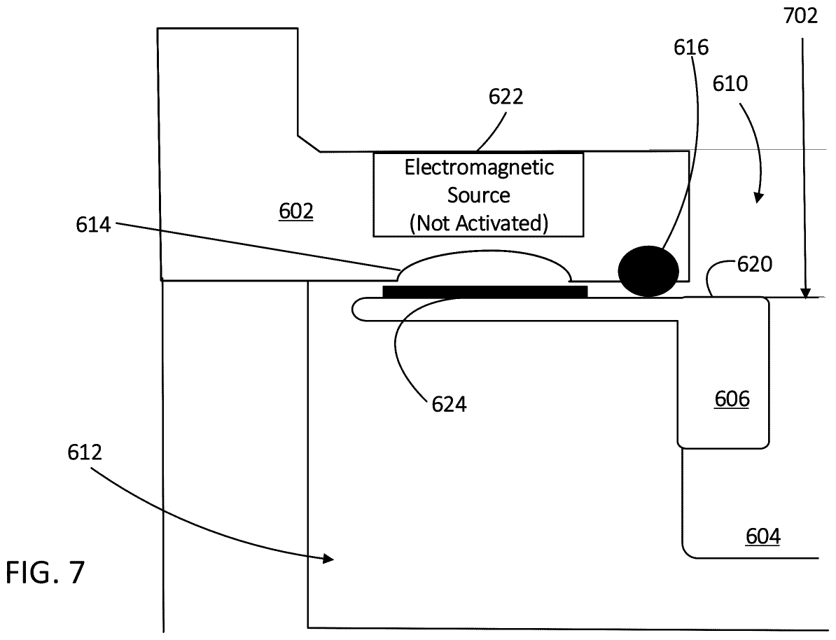

Referring back to FIG. 5, at step 504, the susceptor 604 may be translated upward from a first position 608 (e.g., a lower position or loading position) to a second position (e.g., a raised position or processing position) such that at step 506, an extension plate attached to the susceptor may contact a stopper ring of the spacer plate. For example, as shown in FIG. 7, the susceptor 604 may be translated upward such that the upward-facing surface of the susceptor 604 is at a raised or processing position 702. Furthermore, the flexible diaphragm 624 may be in proximity to the concave portion 614 of the spacer plate 602. The processing position 702 of the susceptor 604 may be the position at which the susceptor 604 is disposed (e.g., at a desired distance from the top or fluid distribution system of the reaction chamber) during the processing of the substrate. During translation, an upward-facing surface 620 of the extension plate 606 may engage with, make contact with, and/or couple to the stopper ring 616 of the spacer plate 602. At step 506, the electromagnetic source 622 is not activated, and therefore, the flexible diaphragm 624 may still be in a relaxed position (e.g., no deformation or expansion).

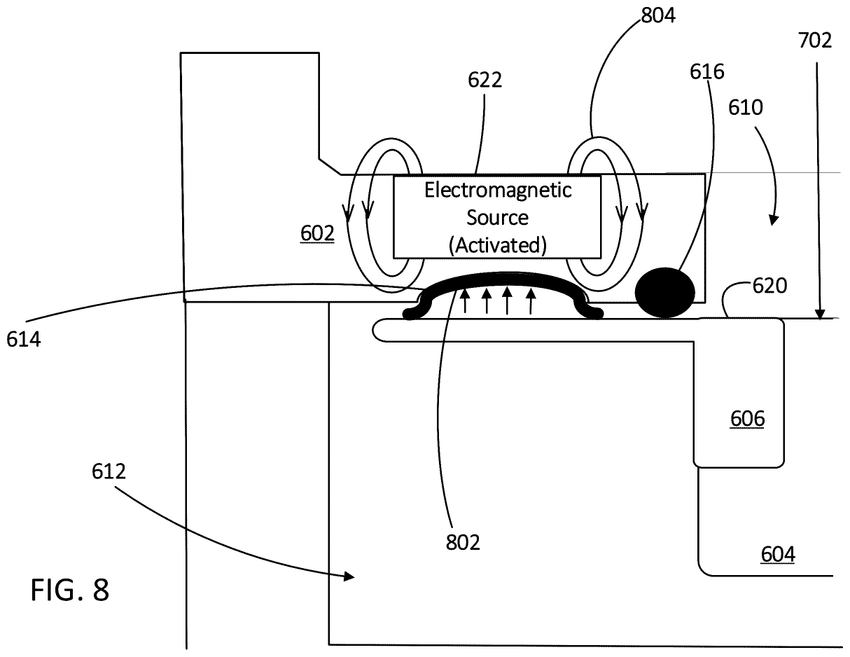

At step 508 of FIG. 5, an upper chamber space and a lower chamber space of the reaction chamber may be isolated by activating an electromagnetic source coupled to the reaction chamber. For example, as illustrated in FIG. 8, the electromagnetic source 622 may be activated to create an electromagnetic field or a magnetic field 804. The flexible diaphragm 624 may comprise a soft or hard magnetic material, and exposing the electromagnetic or magnetic field 804 to the flexible diaphragm 624 may cause a middle portion of the flexible diaphragm 624 to bend, deform, and/or extend toward the concave portion 614 of the spacer plate 602. The bent, deformed, and/or expanded portion 802 of the flexible diaphragm 624 may be in contact with the downward facing surface of the concave portion 614 to form a seal between the bent, deformed, and/or expanded portion 802 of the flexible diaphragm 624 and the concave portion 614 of the spacer plate 602. The electromagnetic source 622 may be activated when the electromagnetic source 622 receives an activation signal from a controller (e.g., the controller 192).

In response to a seal formed between the flexible diaphragm 624 and the spacer plate 602, the upper chamber space 610 may be isolated from the lower chamber space 612. Accordingly, the upper chamber space 610 may be at least partially fluidly isolated from the lower chamber space 612.

At step 510 of FIG. 6, the isolation between the upper chamber space 610 and the lower chamber space 612 may be maintained while a substrate of step 502 is processed within the upper chamber space 610. The isolation may be maintained by keeping the electromagnetic source 622 turned on.

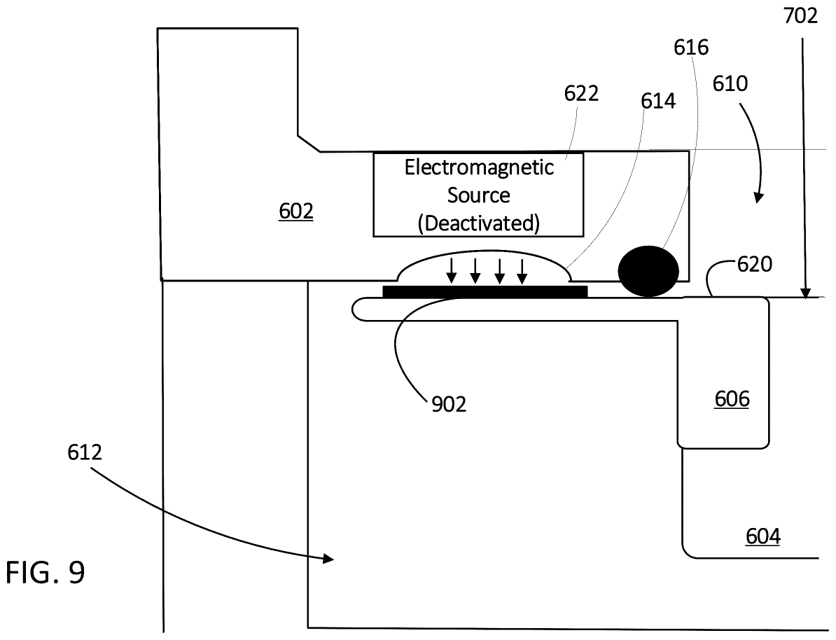

At step 512 of FIG. 5, the electromagnetic source may be deactivated to release the seal between the flexible diaphragm 624 and the spacer plate 602. For example, as illustrated in FIG. 9, the electromagnetic source 622 may be deactivated, which may cause the bent, deformed, and/or expanded portion 802 (as shown in FIG. 8) of the flexible diaphragm 624 to revert to its relaxed condition 902 in the absence of an electromagnetic or magnetic field. The electromagnetic source 622 may be deactivated when receiving a deactivation signal from a controller (e.g., the controller 192).

At step 514 of FIG. 5, the susceptor 604 may translate downward from the raised position (e.g., the raised position 702) to a lower position (e.g., the first position 608 or another lower position). Translating the susceptor downward may allow fluid to flow freely again between the upper chamber space 610 and the lower chamber space 612.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein may be made without departing from the spirit and scope of the present disclosure.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A reaction chamber, comprising:
a susceptor configured to:
support a substrate disposed in the reaction chamber; and
translate upwardly and downwardly within the reaction chamber;
an upper chamber space within the reaction chamber and above the susceptor;
a lower chamber space within the reaction chamber and below the susceptor; and
a sealing system comprising:
a spacer plate surrounding the susceptor; and
a flexible diaphragm coupled to the susceptor,
wherein the sealing system is configured to cause at least partial fluid separation between the upper chamber space and the lower chamber space by causing bending of the flexible diaphragm such that a bent portion of the flexible diaphragm is at least in partial contact with the spacer plate.

2. The reaction chamber of claim 1, wherein the sealing system further comprises an electromagnetic source coupled to the spacer plate, and
wherein the sealing system is configured to cause bending of the flexible diaphragm by:
causing the susceptor to move up within the reaction chamber;
causing an upward-facing surface of the flexible diaphragm to be in proximity to a downward-facing surface of the spacer plate; and
activating the electromagnetic source to expose the flexible diaphragm to an electromagnetic field.

3. The reaction chamber of claim 2, wherein the sealing system further comprises:
a stopper ring attached to the downward-facing surface of the spacer plate, wherein the stopper ring is configured, when the bent portion of the flexible diaphragm is in contact with the spacer plate, to prevent particulates from being deposited on the flexible diaphragm.

4. The reaction chamber of claim 3, wherein the sealing system further comprises an extension plate attached to the susceptor; and
wherein the flexible diaphragm is attached to an upward-facing surface of the extension plate.

5. The reaction chamber of claim 4, wherein the extension plate comprises a non-magnetic metal or a non-magnetic metal alloy.

6. The reaction chamber of claim 4, wherein the sealing system is configured to cause the susceptor to move up within the reaction chamber till the upward-facing surface of the extension plate is in contact with the stopper ring.

7. The reaction chamber of claim 2, wherein the sealing system is further configured to cause fluid communication between the upper chamber space and the lower chamber space by:
deactivating the electromagnetic source; and
causing the susceptor to move down within the reaction chamber.

8. The reaction chamber of claim 1, wherein a downward-facing surface of the spacer plate comprises a concave portion; and
wherein the bent portion of the flexible diaphragm is in contact with the concave portion of the spacer plate.

9. The reaction chamber of claim 1, wherein the flexible diaphragm comprises a magnetic metal or a magnetic metal alloy.

10. The reaction chamber of claim 1, wherein the spacer plate comprises a ceramic material.

11. The reaction chamber of claim 1, wherein the reaction chamber is configured to process the substrate at a temperature of less than 600° C.

12. A sealing system, comprising:
a spacer plate surrounding a susceptor in a reaction chamber;
a flexible diaphragm coupled to the susceptor;
an electromagnetic source coupled to the spacer plate; and
a controller configured to cause at least partial fluid separation between an upper chamber space in the reaction chamber and a lower chamber space in the reaction chamber by:
activating the electromagnetic source to expose the flexible diaphragm to an electromagnetic field; and
causing bending of the flexible diaphragm such that a bent portion of the flexible diaphragm is at least in partial contact with the spacer plate.

13. The sealing system of claim 12, wherein the sealing system further comprises an extension plate attached to the susceptor; and
wherein the flexible diaphragm is attached to an upward-facing surface of the extension plate.

14. The sealing system of claim 13, wherein the sealing system further comprises a stopper ring attached to a downward-facing surface of the spacer plate; and
wherein the controller is further configured to:
before activating the electromagnetic source, cause the susceptor to move up within the reaction chamber till the upward-facing surface of the extension plate is in contact with the stopper ring.

15. The sealing system of claim 12, wherein a downward-facing surface of the spacer plate comprises a concave portion; and
wherein the bent portion of the flexible diaphragm is in contact with the concave portion of the spacer plate.

16. The sealing system of claim 12, wherein the controller is further configured to cause fluid communication between the upper chamber space and the lower chamber space by deactivating the electromagnetic source.

17. A method, comprising:
translating a susceptor, in a reaction chamber, upwardly from a first position to a second position, wherein the reaction chamber comprises an upper chamber space above the susceptor and a lower chamber space below the susceptor;
causing at least partial fluid separation between the upper chamber space and the lower chamber space by:
activating an electromagnetic source to expose a flexible diaphragm, coupled to the susceptor, to an electromagnetic field; and
causing, based on the electromagnetic field, bending of the flexible diaphragm such that a bent portion of the flexible diaphragm is at least in partial contact with a spacer plate surrounding the susceptor; and
maintaining, during processing of a substrate within the upper chamber space, the partial fluid separation between the upper chamber space and the lower chamber space.

18. The method of claim 17, wherein the translating the susceptor to the second position comprises causing an upward-facing surface, of an extension plate attached to the susceptor, to be in contact with a stopper ring coupled to a downward-facing surface of the spacer plate, wherein the flexible diaphragm is attached to the upward-facing surface of the extension plate.

19. The method of claim 17, wherein a downward-facing surface of the spacer plate comprises a concave portion; and
wherein the bent portion of the flexible diaphragm is in contact with the concave portion of the spacer plate.

20. The method of claim 17, further comprising:
after the processing of the substrate:
deactivating the electromagnetic source; and
translating the susceptor downward from the second position to a third position.
